(19) United States
(12) Patent Application Publication
(10) Pub. No.: US 2018/0138932 A1
(43) Pub. Date: May 17, 2018

(54) TRANSMITTING CIRCUIT AND ASSOCIATED SIGNAL TRANSMITTING METHOD

(71) Applicant: MStar Semiconductor, Inc., Hsinchu Hsien (TW)

(72) Inventors: Tzu-Hsuan Huang, Hsinchu County (TW); Yun-Liang Su, Hsinchu County (TW); TAI-LAI TUNG, Hsinchu County (TW)

(21) Appl. No.: 15/486,417

(22) Filed: Apr. 13, 2017

(30) Foreign Application Priority Data
Nov. 15, 2016 (TW) 105137174

(51) Int. Cl. H04B 1/04; H04B 3/46; H03G 3/30

(52) U.S. Cl. CPC H04B 1/04; H04B 17/336; H03G 3/3089; H04B 3/46

(57) ABSTRACT

A transmitting circuit is disposed in an electronic device, which performs signal transmission with another electronic device through an Ethernet over Coax (EoC) system. The transmitting circuit includes a control circuit, a gain adjusting circuit and an output circuit. The control circuit obtains a tone map from the other electronic device, calculates a signal quality parameter according to the tone map, and determines a gain according to the signal quality parameter. The gain adjusting circuit, coupled to the control circuit, adjusts the strength of a signal according to the gain to generate an adjusted signal. The output circuit, coupled to the gain adjusting circuit, transmits the adjusted signal to the other electronic device.

This application claims the benefit of Taiwan application Serial No. 105137174, filed Nov. 15, 2016, the subject matter of which is incorporated herein by reference.

### BACKGROUND OF THE INVENTION

### Field of the Invention

The invention relates in general to a transmitter, and more particularly to a transmitter in an Ethernet over Coax (EoC) system and an associated signal transmitting method.

### Description of the Related Art

In a current transmitter applied in an Ethernet over Coax (EoC) system, considering a linear working area of a driving circuit as well as a higher requirement on the signal-to-noise ratio (SNR) of the signal if the transmitter adopts certain signal modulation schemes, a gain of the transmitter is designed as a constant value to prevent the SNR from degrading as the gain of the transmitter increases. However, such method not only compromises operation flexibilities of the transmitter but is also incapable of achieving an optimum throughput of the transmitter.

### SUMMARY OF THE INVENTION

The invention is directed to a transmitter having a gain that can be dynamically adjusted according to channel quality conditions. Thus, under different channel quality conditions, the transmitter may provide an appropriate throughput through different settings to solve the issues of the prior art.

A transmitting circuit is disclosed according to an embodiment of the present invention. The transmitting circuit is disposed in an electronic device, which performs signal transmission with another electronic device through an Ethernet over Coax (EoC) system. The transmitting circuit includes a control circuit, a gain adjusting circuit and an output circuit. The control circuit obtains a tone map from the other electronic device, calculates a signal quality parameter according to the tone map, and determines a gain according to the signal quality parameter. The gain adjusting circuit, coupled to the control circuit, adjusts the strength of a signal according to the gain to generate an adjusted signal. The output circuit, coupled to the gain adjusting circuit, transmits the adjusted signal to the other electronic device.

A signal transmitting method is disclosed according to another embodiment of the present invention. The signal transmitting method is applied to an electronic device, which performs signal transmission with another electronic device through an EoC system. The signal transmitting method includes: obtaining a tone map from the other electronic device; calculating a signal quality parameter according to the tone map; determining a gain according to the signal quality parameter; adjusting the strength of a signal according to the gain to generate an adjusted signal; and transmitting the adjusted signal to the other electronic device.

A set-up box (STB) is disclosed according to another embodiment of the present invention. The STB performs signal transmission with another electronic device through an EoC system, and includes a de-packetizing circuit, a determining circuit, a control circuit, a gain adjusting circuit and an output circuit. The de-packetizing circuit de-packetizes a packet transmitted from the other electronic device to obtain a tone map. The determining circuit calculates a signal quality parameter according to the tone map. The control circuit determines a gain according to the signal quality parameter. The gain adjusting circuit adjusts the strength of a signal according to the gain to generate an adjusted signal. The output circuit transmits the adjusted signal to the other electronic device. The signal is generated according to the tone map.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1 is a block diagram of an Ethernet over Coax (EoC) system;

FIG. 2 is a block diagram of a transmitting circuit according to an embodiment of the present invention;

FIG. 3 is a timing diagram of adjusting a gain of a transmitting circuit according to a tone map index according to an embodiment of the present invention; and

FIG. 4 is a flowchart of a signal transmitting method according to an embodiment of the present invention.

### DETAILED DESCRIPTION OF THE INVENTION

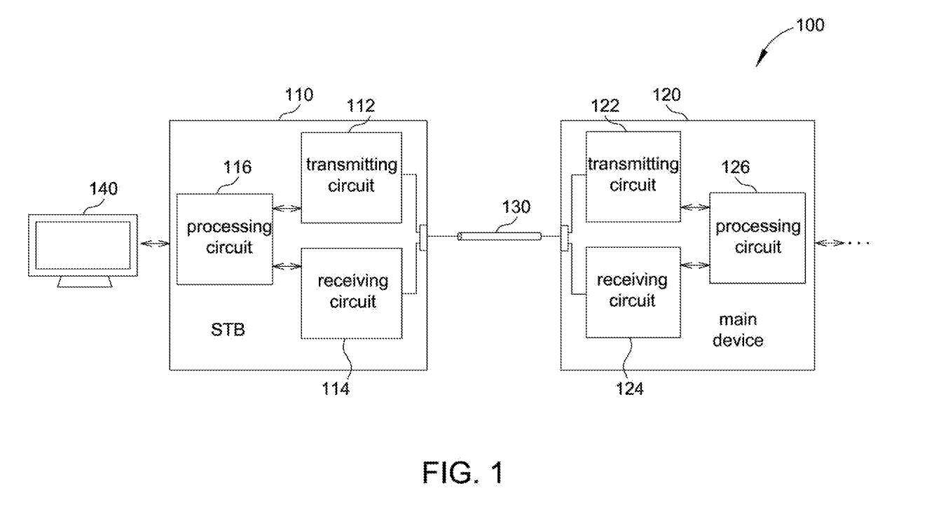

FIG. 1 shows a block diagram of an Ethernet over Coax (EoC) system 100. In FIG. 1, the EoC system 100 includes a set-top box (STB) 110 and a main device 120. The STB 110 and the main device 120 perform audio/video signal and digital data transmission through a cable 130. In addition to transmitting the audio/video signals from the main device 120 to a display device for playback, the STB 110 further transmits the digital data from the main device 120 to a computer device for processing and transmits digital data from the computer device to the main device 120. In the embodiment, for example, a smart television 140 includes the display device and the computer device. In an alternative embodiment, the display device and the computer device may be different devices. In the embodiment in FIG. 1, the STB 110 includes a transmitting circuit 112, a receiving circuit 114 and a processing circuit 116 that perform data processing, transmission and reception. The main device 120 includes a transmitting circuit 122, a receiving circuit 124 and a processing circuit 126 that perform data processing, transmission and reception.

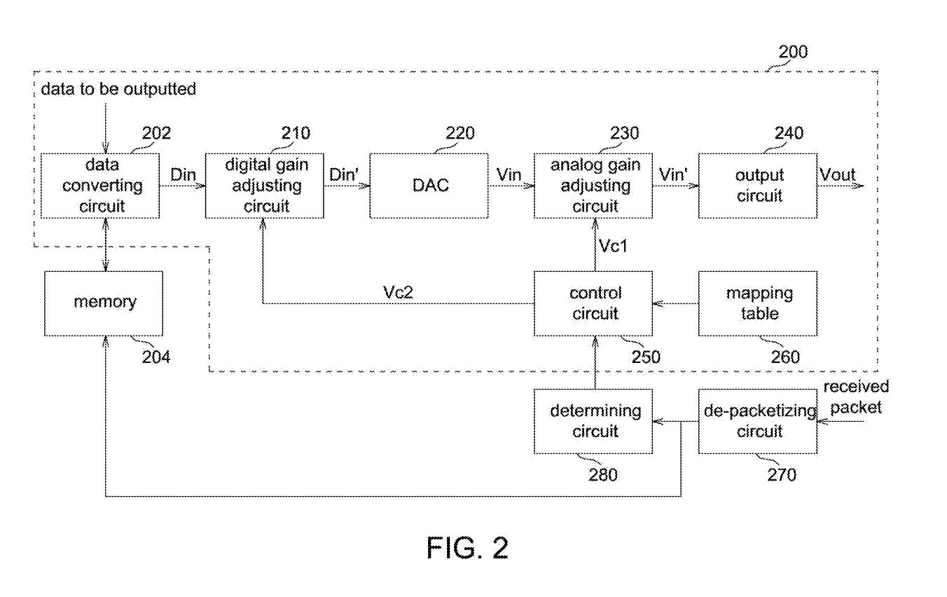

FIG. 2 shows a block diagram of a transmitting circuit 200 according to an embodiment of the present invention. As shown in FIG. 2, the transmitting circuit 200 includes a data converting circuit 202, a digital gain adjusting circuit 210, a digital-to-analog converter (DAC) 220, an analog gain adjusting circuit 230, an output circuit 240, a control circuit 250 and a mapping table 260. The transmitting circuit 200 is further coupled to a memory 204, a de-packetizing circuit 270 and a determining circuit 280. In the embodiment, the analog gain adjusting circuit 230 may be an analog frontend circuit module that includes an amplifying circuit, and the output circuit 240 may include a low-noise amplifier and associated driving circuits. The transmitting circuits 112 and 122 in FIG. 1 may both be implemented by the transmitting circuit 200, the determining circuit 280 may be disposed in the processing circuits 116 and 126, and the de-packetizing circuit 270 may be disposed in the receiving circuits 114 and 124.

The mapping table 260 in FIG. 2 stores gains corresponding to different signal quality parameters. More specifically, a signal quality parameter represents signal quality of a signal being transmitted in a transmission channel (e.g., the cable 130), e.g., whether the signal attenuation level is high or low. Further, the mapping table 260 stores a first gain Vc1 and a second gain Vc2 corresponding to the different signal quality parameters. The first gain Vc1 is for the use of the analog gain adjusting circuit 230, and the second gain Vc2 is for the use of the digital gain adjusting circuit 210.

In an operation of the transmitting circuit 200, the de-packetizing circuit 270 receives a packet and de-packetizes the packet to obtain a tone map, and transmits the tone map to the determining circuit 280 and the memory 204. More specifically, a data format of the packet includes a header part and a data part. The header part includes a plurality of cyclic sequences and signal frame information, e.g., a starting position of the data part; the data part may be data or a carrier modulation mode map (or referred to as a tone map). When the de-packetizing circuit 270 confirms that the data part is the tone map according to the header part, the de-packetizing circuit 270 transmits the tone map to the determining circuit 280 and the memory 204. The determining circuit 280 determines a signal quality parameter according to the received tone map. More specifically, in an EoC system, the tone map records modulation modes corresponding to different signal components (e.g., carriers) by using different bit counts, e.g., the 1^{st} signal component is N-bit, the 2^{nd} signal component is M-bit . . . etc. For example but not limited to, the determining circuit 280 may calculate an average bit count of all of the signal components as the signal quality parameter. The control circuit 250 determines the first gain Vc1 and the second gain Vc2 respectively to be used by the analog gain adjusting circuit 230 and the digital gain adjusting circuit 210 according to the signal quality parameter and the mapping table 260. The data converting circuit 202 converts the data format of the data to be outputted according to the tone map stored in the memory 204 to generate a digital signal Din. The digital gain adjusting circuit 210 adjusts the strength of the digital signal Din according to the second gain Vc2 to generate an adjusted digital signal Din′. The DAC 220 performs a digital-to-analog conversion on the adjusted digital signal Din′ to generate an analog signal Vin. The analog gain adjusting circuit 230 adjusts the strength of the analog signal Vin according to the first gain Vc1 to generate an adjusted analog signal Vin′. The output circuit 240 processes the adjusted analog signal Vin′, which is then transmitted via the cable 230.

In the embodiment, when the signal quality parameter indicates that the signal transmission quality is better, the control circuit 250 generates the first gain Vc1 and the second gain Vc2 in a way that a total gain of the analog gain adjusting circuit 230 and the digital gain adjusting circuit 210 is lower. Conversely, when the signal quality parameter indicates that the signal transmission quality is poorer, the control circuit 250 generates the first gain Vc1 and the second gain Vc2 in a way that the total gain of the analog gain adjusting circuit 230 and the digital gain adjusting circuit 210 is higher.

In the embodiment the data converting circuit 202 adopts different digital signal modulation schemes according to different channel conditions (e.g., the channel quality parameter), e.g., adopting 4096 quadrature amplitude modulation (4096 QAM) when there is less channel fading, or adopting quadrature phase-shift keying (QPSK) when there is more channel fading. However, because an environment with better signal transmission quality (e.g., a higher SNR) is needed when 4096 QAM is adopted, the control circuit 250 controls the analog gain adjusting circuit 230 and the digital gain adjusting circuit 210 to have a lower total gain, so as to prevent from exceeding a linear working range of the transmitting circuit 200 and hence from affecting the SNR. On the other hand, because the QPSK modulation scheme does not required an excellent signal transmission quality environment, the control circuit 250 controls the analog gain adjusting circuit 230 and the digital gain adjusting circuit 210 to have a higher total gain in order to increase the throughput of the transmitting circuit 200, even if it means the linear working range of the transmitting circuit 200 is exceeded and the signal transmission quality is sacrificed. As previously discussed, since the gain of the transmitting circuit 200 may be dynamically adjusted according to channel quality conditions, the transmitting circuit 200 is provided with most suitable and flexible settings under different channel quality conditions, hence solving issues of the prior art.

In one embodiment of the present invention, considering that a peak to average power ratio (PAPR) of an output signal Vout of the transmitting circuit 200 and the number of bit count that the DAC 220 is capable of processing, the digital gain adjusting circuit 210 may reduce the strength of the digital signal Din merely according to the second gain Vc2 or not adjust the strength of the digital signal Din at all, i.e., the second gain Vc2 is smaller than or equal to 1. To coordinate with the second gain Vc2, the first gain Vc1 needs to be greater than or equal to 1, such that the total gain is a positive value. Further, in one embodiment, the amounts of gain adjustment of the analog gain adjusting circuit 230 and the digital gain adjusting circuit 210 may be different to allow the overall gain adjustment of the transmitting circuit 200 to be more precise. For example, the amount of gain adjustment of the analog gain adjusting circuit 230 may be in a unit of 3 dB, and the amount of gain adjustment of the digital gain adjusting circuit 210 may be in a unit of (−2) dB, such that the precision of the overall gain adjustment of the transmitting circuit 200 is 1 dB.

In the embodiment in FIG. 2, the control circuit 250 determines the gains to be used by the analog gain adjusting circuit 230 and the digital gain adjusting circuit 210 according to the signal quality parameter. However, the above is not to be construed as a limitation to the present invention. In an alternative embodiment of the present invention, the control circuit 250 may determine one of the first gain Vc1 and the second gain Vc2 according to the signal quality parameter; that is, only the gain of one of the analog gain adjusting circuit 230 and the digital gain adjusting circuit 210 dynamically changes with the signal quality parameter. The above design variations are encompassed within the scope of the present invention.

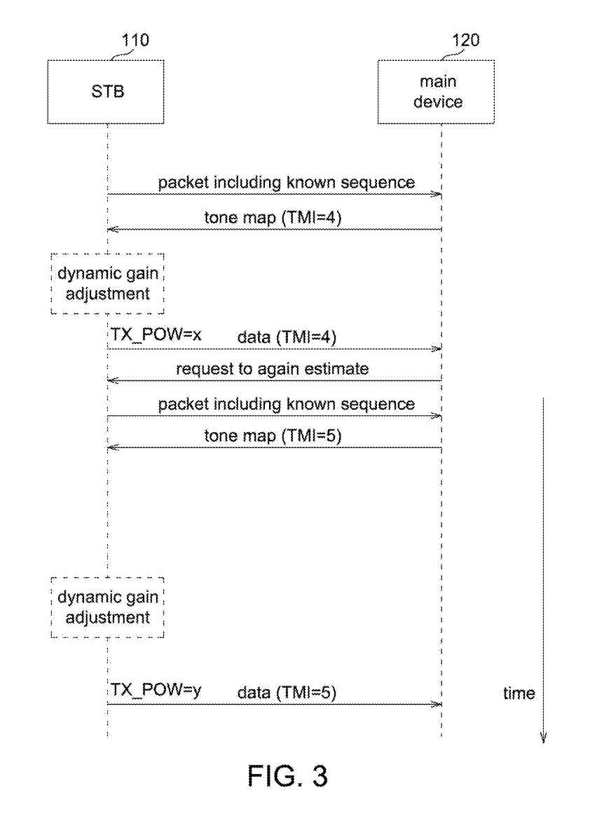

FIG. 3 shows a timing diagram of adjusting the gain of the transmitting circuit 200 according to a signal quality parameter. In FIG. 3, it is assumed that the STB 110 is a transmitter, and the main device 120 is a receiver. As shown in FIG. 3, the STB 110 first transits a packet (e.g., a training packet) having a known sequence to the main device 120. The main device 120 then performs channel estimation on the received packet to determine a tone map (e.g., a tone map having a tone map index 4), and transmits the tone map in form of a packet to the STB 110. After receiving the packet from the main device 120, the de-packetizing circuit 270 of the STB 110 obtains the tone map (TMI=4) and stores the tone map to the memory 204. The determining circuit 280 calculates the average bit count of all of the signal components according to the bit counts corresponding to multiple different signal components included in the tone map as a signal quality parameter. Next, the control circuit 250 dynamically determines a transmission power (i.e., determining the first gain Vc1 and/or the second gain Vc2) according to the signal quality parameter, and uses a transmission power TX_POW=“x” to transmit data to the main device 120. The transmission power TX_POW is the overall total gain. Further, the transmitted data is obtained from converting data to be transmitted according to the tone map (TMI=4) stored in the memory 204 by the data converting circuit 202.

After receiving the data from the STB 110, the main device 120 again performs channel estimation on the received data. If the received signal quality is poor, .e., the SNR of the received signal is lower than a threshold, the main device 120 sends a request to the STB 100 to ask for another round of channel estimation. After receiving the request for another round of channel estimation, similarly, the STB 110 again transmits a packet having a known sequence to the main device 120. The main device 120 again performs channel estimation on the received packet, determines a tone map (e.g., TMI=5), and transmits the tone map in form of a packet to the STB 110. The STB 110 stores the tone map (TMI=5) in the packet to the memory 204, and obtains the updated channel quality parameter according to the tone map. Next, the STB 110 dynamically determines an updated transmission power according to the updated channel quality parameter, and uses the transmission power TX_POW=“y” to transmit data to the main device 120. Further, the transmitted data at this point is obtained from converting the data to be transmitted according to the tone map (TMI=5) by the data converting circuit 202.

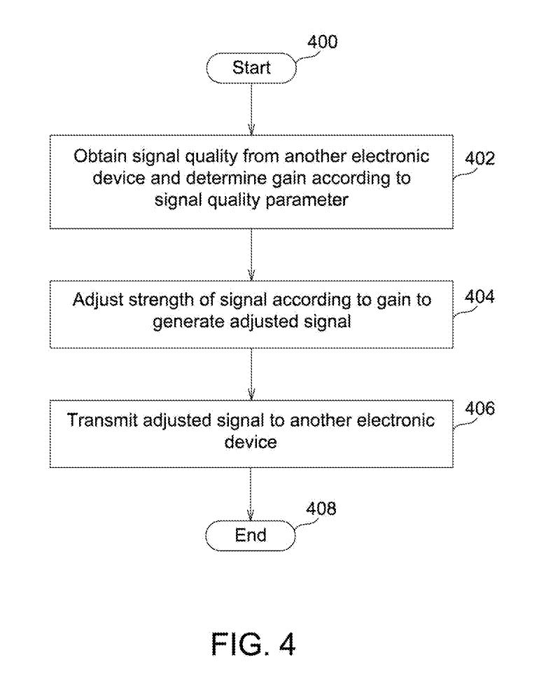

FIG. 4 shows a flowchart of a signal transmitting method according to an embodiment of the present invention. Referring to the description disclosed in the foregoing embodiments, the process in FIG. 4 is as follows.

In step 400, the process begins.

In step 402, a signal quality parameter is obtained from another electronic device, and a gain is determined according to the signal quality parameter.

In step 404, the strength of a signal is adjusted according to the gain to generate an adjusted signal.

In step 406, the adjusted signal is transmitted to other electronic device.

In step 408, the process ends.

In conclusion, in the embodiments of the present invention, the gain of the transmitter may be dynamically adjusted according to the channel quality conditions. When the channel quality is better, the gain of the transmitter may be reduced to allow the transmitted signal to have a better SNR as the transmitter operates within the linear working range. When the channel quality is poorer, the gain of the transmitter is increased to compromise the SNR for a larger throughput. Thus, the transmitter is provided with most appropriate and most flexible settings under different channel quality conditions.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A transmitting circuit, disposed in an electronic device, the electronic device performing signal transmission with another electronic device through an Ethernet over Coax (EoC) system, the transmitting circuit comprising:
a control circuit, obtaining a tone map from the another electronic device, calculating a signal quality parameter according to the tone map, and determining a gain according to the signal quality parameter;
a gain adjusting circuit, coupled to the control circuit, adjusting a strength of a signal according to the gain to generate an adjusted signal; and
an output circuit, coupled to the gain adjusting circuit, transmitting the adjusted signal to the another electronic device.

2. The transmitting circuit according to claim 1, wherein the gain adjusting circuit is an analog gain adjusting circuit, the signal is an analog signal, the gain is a first gain, the control circuit further determines a second gain according to the signal quality parameter, the transmitting circuit further comprising:
a digital gain adjusting circuit, adjusting a strength of a digital signal according to the second gain to generate an adjusted digital signal; and
a digital-to-analog converter (DAC), coupled to the digital gain adjusting circuit and the analog gain adjusting circuit, performing a digital-to-analog conversion on the adjusted digital signal to generate the analog signal.

3. The transmitting circuit according to claim 2, wherein the control circuit determines that the first gain is greater than 1 and the second gain is smaller than 1.

4. The transmitting circuit according to claim 1, wherein the signal is a first signal, the gain adjusting circuit is a first gain adjusting circuit, the gain is a first gain, the control circuit further determines a second gain according to the signal quality parameter, the transmitting circuit further comprising:
a second gain adjusting circuit, adjusting a second signal according to the second gain;
wherein, the first signal is generated according to the second signal, and the first gain is greater than 1 and the second gain is smaller than 1.

5. The transmitting circuit according to claim 4, wherein the first gain adjusting circuit is an analog gain adjusting circuit, the first signal is an analog signal, the second gain adjusting circuit is a digital gain adjusting circuit, the second signal is a digital signal, the transmitting circuit further comprising:
a digital-to-analog converter (DAC), coupled to the digital gain adjusting circuit and the analog gain adjusting circuit, performing a digital-to-analog conversion on the adjusted second signal to generate the first signal.

6. The transmitting circuit according to claim 1, wherein the electronic device is a set-top box (STB).

7. The transmitting circuit according to claim 1, wherein the tone map comprises bit counts respectively corresponding to a plurality of carriers, and the signal quality parameter is calculated according to the bit counts corresponding to the carriers.

8. The transmitting circuit according to claim 7, wherein the signal quality parameter is an average of the bit counts corresponding to the carriers.

9. A signal transmitting method, applied to an electronic device, the electronic device performing signal transmission with another electronic device through an Ethernet over Coax (EoC) system, the signal transmitting method comprising:
obtaining a tone map from the another electronic device;
calculating a signal quality parameter according to the tone map;
determining a gain according to the signal quality parameter;
adjusting a strength of a signal according to the gain to generate an adjusted signal; and
transmitting the adjusted signal to the another electronic device.

10. The signal transmitting method according to claim 9, wherein the signal is an analog signal, the gain is a first gain, the signal transmitting method further comprising:
determining a second gain according to the signal quality parameter;
adjusting a strength of a digital signal according to the second gain to generate an adjusted digital signal; and
performing a digital-to-analog conversion on the adjusted digital signal to generate the analog signal.

11. The signal transmitting method according to claim 10, wherein it is determined that the first gain is greater than 1 and the second gain is smaller than 1 according to the signal quality parameter.

12. The signal transmitting method according to claim 9, wherein the signal is a first signal, the gain is a first gain, the signal transmitting method further comprising:
determining a second gain according to the signal quality parameter; and
adjusting a second signal according to the second gain;
wherein, the first signal is generated according to the second signal, and the first gain is greater than 1 and the second gain is smaller than 1.

13. The signal transmitting method according to claim 12, wherein the first signal is an analog signal, the second signal is a digital signal, the signal transmitting method further comprising:
performing a digital-to-analog conversion on the adjusted second signal to generate the first signal.

14. The signal transmitting method according to claim 9, wherein the electronic device is a set-top box (STB).

15. The signal transmitting method according to claim 9, wherein the tone map comprises bit counts respectively corresponding to a plurality of carriers, and the step of calculating the signal quality parameter according to the tone map comprises:
calculating the signal quality parameter according to the bit counts corresponding to the carriers.

16. The signal transmitting method according to claim 15, wherein the step of calculating the signal quality parameter according to the tone map comprises:
calculating an average of the bit counts corresponding to the carriers as the signal quality parameter.

17. A set-top box (STB), performing signal transmission with another electronic device through an Ethernet over Coax (EoC) system, comprising:
a de-packetizing circuit, de-packetizing a packet transmitted from the another electronic device to obtain a tone map;
a determining circuit, calculating a signal quality parameter according to the tone map;
a control circuit, determining a gain according to the signal quality parameter;
a gain adjusting circuit, adjusting a strength of a signal according to the gain to generate an adjusted signal; and
an output circuit, transmitting the adjusted signal to the another electronic device;
wherein, the signal is generated according to the tone map.
